(19) United States
(12) Patent Application Publication
(10) Pub. No.: US 2025/0324793 A1
(43) Pub. Date: Oct. 16, 2025

(54) OPTICAL PROTECTION STRUCTURE AND METHOD FOR FORMING THE SAME

(71) Applicant: VisEra Technologies Company Limited, Hsin-Chu City (TW)

(72) Inventors: Hao-Wei LIU, Hsin-Chu City (TW); Shin-Hong KUO, Hsin-Chu City (TW); Ching-Chiang WU, Hsin-Chu City (TW); Han-Lin WU, Hsin-Chu City (TW); Hung-Jen TSAI, Hsin-Chu City (TW)

(21) Appl. No.: 18/636,636

(22) Filed: Apr. 16, 2024

(51) Int. Cl. H01L 27/146

(52) U.S. Cl. CPC H10F 39/8057; H10F 39/024; H10F 39/804

(57) ABSTRACT

An optical protection structure is provided. The optical protection structure includes a transparent substrate and a first anti-reflective structure disposed on one side of the transparent substrate. The first anti-reflective structure has a first light-path region, a first raised region surrounding the first light-path region, and a first step region between the first light-path region and the first raised region. The first anti-reflective structure includes first nano-structures in the first light-path region, and a first contact surface is defined between the first nano-structures and the transparent substrate. The thickness of the first anti-reflective structure in the first raised region from the first contact surface is greater than the thickness of the first anti-reflective structure in the first light-path region from the first contact surface.

### BACKGROUND OF THE INVENTION

### Field of the Invention

The present invention relates to a protection structure, and, in particular, to an n optical protection structure for an image sensor.

### Description of the Related Art

Solid-state image sensors (e.g., complementary metal-oxide semiconductor (CMOS) image sensors) have been widely used in various image-capturing apparatuses such as digital still-image cameras, digital video cameras, and the like. Signal electric charges may be generated according to the amount of light received in the light-sensing portion (e.g., the photoelectric conversion element) of the solid-state image sensor. In addition, the signal electric charges generated in the light-sensing portion may be transmitted and amplified, whereby an image signal is obtained.

In general solid-state image sensors, flat glass with multi-film layers are commonly used to protect the light-emitting structures, which may also possess anti-reflective properties. Alternately, since nano-structures have better anti-reflection and transmittance properties, especially at long wavelengths and wide incident angles, they may be used in solid-state image sensors. However, nano-structures have weak mechanical properties, and therefore they are prone to structural damage and breakage during the forming process.

### BRIEF SUMMARY OF THE INVENTION

According to the embodiment of the present disclosure, the optical protection structure includes at least one anti-reflective structure that has a light-path region, a raised region surrounding the light-path region, and a step region between the first light-path region and the first raised region. It may effectively prevent the anti-reflective structure from being damaged during the forming process and provide better anti-reflection and transmittance at long-wavelength and large incident angle.

An embodiment of the present disclosure provides an optical protection structure. The optical protection structure includes a transparent substrate and a first anti-reflective structure disposed on one side of the transparent substrate. The first anti-reflective structure has a first light-path region, a first raised region surrounding the first light-path region, and a first step region between the first light-path region and the first raised region. The first anti-reflective structure includes first nano-structures in the first light-path region, and a first contact surface is defined between the first nano-structures and the transparent substrate. The thickness of the first anti-reflective structure in the first raised region from the first contact surface is greater than the thickness of the first anti-reflective structure in the first light-path region from the first contact surface.

In some embodiments, the thickness of the first anti-reflective structure in the first raised region from the first contact surface is at least twice the thickness of the first anti-reflective structure in the first light-path region from the first contact surface.

In some embodiments, from a cross-sectional view, the width of the first raised region is at least ten times the width of each first nano-structure.

In some embodiments, the ratio of the distance between two adjacent first nano-structures to the thickness of the first anti-reflective structure in the first light-path region from the first contact surface is smaller than 2.

In some embodiments, from a cross-sectional view, the width of the first step region is greater than 5 nm, and a sharp corner or a rounded corner is formed between the first raised region and the first step region.

In some embodiments, the first nano-structures are formed as pillars, cones, prisms, or pyramids.

In some embodiments, the first nano-structures are formed into multiple protruding structures that define multiple holes.

In some embodiments, the transparent substrate has recessed portions that correspond to the first light-path region and the first step region, and the first nano-structures are disposed in the recessed portions.

In some embodiments, the first anti-reflective structure further includes light-shielding structures in the first raised region.

In some embodiments, the optical protection structure further includes a second anti-reflective structure disposed on another side of the transparent substrate. The second anti-reflective structure has a second light-path region, a second raised region surrounding the second light-path region, and a second step region between the second light-path region and the second raised region. The second light-path region corresponds to the first light-path region, and the second raised region corresponds to the first raised region. The second anti-reflective structure comprises second nano-structures in the second light-path region, and a second contact surface is defined between the second nano-structures and the transparent substrate. The thickness of the second anti-reflective structure in the second raised region from the second contact surface is greater than the thickness of the second anti-reflective structure in the second light-path region from the second contact surface.

In some embodiments, the thickness of the second anti-reflective structure in the second raised region from the second contact surface is at least twice the thickness of the second anti-reflective structure in the second light-path region from the second contact surface.

In some embodiments, from a cross-sectional view, the width of the second raised region is at least ten times the width of each second nano-structure.

In some embodiments, the ratio of the distance between two adjacent second nano-structures to the thickness of the second anti-reflective structure in the second light-path region from the second contact surface is smaller than 2.

In some embodiments, from a cross-sectional view, the width of the second step region is greater than 5 nm, and a sharp corner or a rounded corner is formed between the second raised region and the second step region.

In some embodiments, the second nano-structures are formed as pillars, cones, prisms, or pyramids.

In some embodiments, the second nano-structures are formed into multiple protruding structures that define multiple holes.

An embodiment of the present disclosure provides a method for forming an optical protection structure, which includes the following steps. A first anti-reflective film is formed on one side of a transparent substrate. The first anti-reflective film is patterned to form a first anti-reflective structure. The first anti-reflective structure has a first light-path region, a first raised region surrounding the first light-path region, and a first step region between the first light-path region and the first raised region. The first anti-reflective structure includes first nano-structures in the first light-path region, and a first contact surface is defined between the first nano-structures and the transparent substrate. The thickness of the first anti-reflective structure in the first raised region from the first contact surface is greater than the thickness of the first anti-reflective structure in the first light-path region from the first contact surface.

In some embodiments, the method for forming the optical protection structure further includes the following step. The transparent substrate is patterned to form recessed portions by a wet etching process, so that a portion of the first anti-reflective film is formed in the recessed portions. The first light-path region and the first step region correspond to the recessed portions, and the first nano-structures are disposed in the recessed portions.

In some embodiments, the steps of patterning the first anti-reflective film includes the following steps. A first dry etching process is performed on the first anti-reflective film to form the first raised region and a recess portion. A second dry etching process is performed on the recess portion to form the first light-path region and the first step region.

In some embodiments, the method for forming the optical protection structure further includes the following steps. A second anti-reflective film is formed on another side of the transparent substrate. The second anti-reflective film is patterned to form a second anti-reflective structure. The second anti-reflective structure has a second light-path region, a second raised region surrounding the second light-path region, and a second step region between the second light-path region and the second raised region. The second anti-reflective structure includes second nano-structures in the second light-path region, and a second contact surface is defined between the second nano-structures and the transparent substrate. The thickness of the second anti-reflective structure in the second raised region from the second contact surface is greater than the thickness of the second anti-reflective structure in the second light-path region from the second contact surface.

### BRIEF DESCRIPTION OF THE DRAWINGS

The disclosure can be more fully understood from the following detailed description when read with the accompanying figures. It is worth noting that, in accordance with standard practice in the industry, various features are not drawn to scale. In fact, the dimensions of the various features may be arbitrarily increased or reduced for clarity of discussion.

FIG. 1A is a partial cross-sectional view illustrating an optical protection structure according to some embodiments of the present disclosure.

FIG. 1B is a partial top view illustrating the first anti-reflective structure according to some embodiments of the present disclosure.

FIG. 2A to FIG. 2G are partial cross-sectional views illustrating a method for forming the optical protection structure at various stages according to some embodiments of the present disclosure.

FIG. 3 is a partial cross-sectional view illustrating a stage for bonding the optical protection structure to a solid-state image sensor.

FIG. 4A is a partial cross-sectional view illustrating an optical protection structure according to some other embodiments of the present disclosure.

FIG. 4B is a partial top view illustrating the first anti-reflective structure according to some embodiments of the present disclosure.

FIG. 5A to FIG. 5G are partial cross-sectional views illustrating a method for forming the optical protection structure at various stages according to some other embodiments of the present disclosure.

FIG. 6 is a partial cross-sectional view illustrating a stage for bonding the optical protection structure to a solid-state image sensor.

FIG. 7A illustrates the reflectivity of the traditional optical protection structure and the reflectivity of the optical protection structure according to the embodiment of the present disclosure at various wavelengths.

FIG. 7B illustrates the transmittance of the traditional optical protection structure and the reflectivity of the optical protection structure according to the embodiment of the present disclosure at various wavelengths.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, a first feature is formed on a second feature in the description that follows may include embodiments in which the first feature and second feature are formed in direct contact, and may also include embodiments in which additional features may be formed between the first feature and second feature, so that the first feature and second feature may not be in direct contact.

It should be understood that additional steps may be implemented before, during, or after the illustrated methods, and some steps might be replaced or omitted in other embodiments of the illustrated methods.

Furthermore, spatially relative terms, such as “beneath,” “below,” “lower,” “on,” “above,” “upper” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the present disclosure, the terms “about,” “approximately” and “substantially” typically mean +/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. That is, when there is no specific description of the terms “about,” “approximately” and “substantially”, the stated value includes the meaning of “about,” “approximately” or “substantially”.

Unless otherwise defined, all terms (including technical and scientific terms) used herein have the same meaning as commonly understood by one of ordinary skill in the art to which this disclosure belongs. It should be understood that terms such as those defined in commonly used dictionaries should be interpreted as having a meaning that is consistent with their meaning in the context of the relevant art and will not be interpreted in an idealized or overly formal sense unless expressly so defined in the embodiments of the present disclosure.

The present disclosure may repeat reference numerals and/or letters in following embodiments. This repetition is for the purpose of simplicity and clarity and does not in itself dictate a relationship between the various embodiments and/or configurations discussed

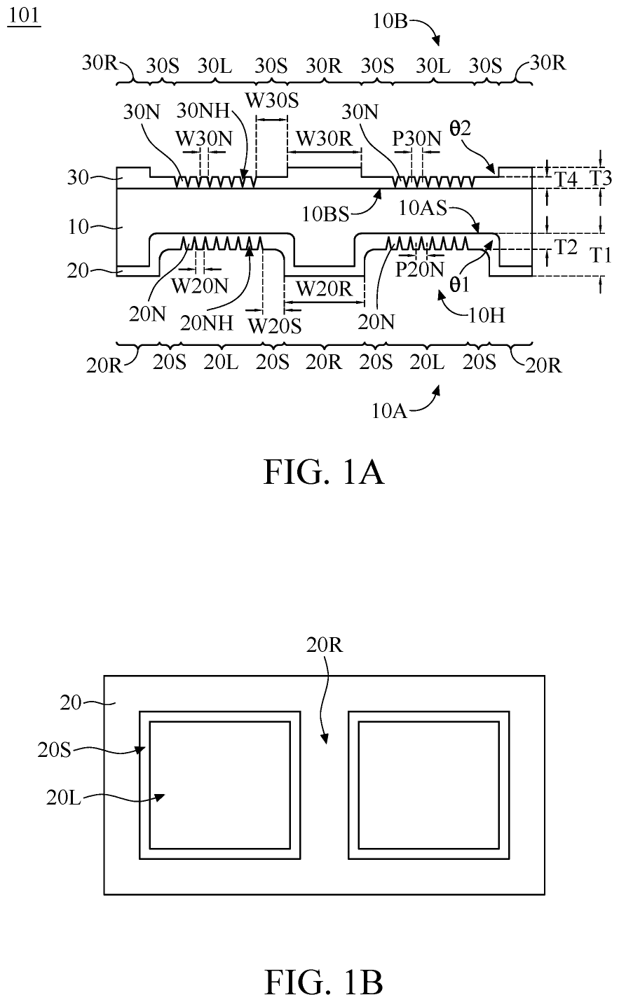

FIG. 1A is a partial cross-sectional view illustrating an optical protection structure 101 according to some embodiments of the present disclosure. The optical protection structure 101 may be used in a solid-state image sensor for protection and anti-reflection. It should be noted that some components of the optical protection structure 101 have been omitted in FIG. 1A for the sake of brevity.

Referring to FIG. 1A, in some embodiments, the optical protection structure 101 includes a transparent substrate 10. For example, the transparent substrate 10 may include a transparent material, such as glass, epoxy resin, silicone resin, polyurethane, any other applicable material, or a combination thereof, but the present disclosure is not limited thereto.

Referring to FIG. 1A, in some embodiments, the optical protection structure 101 includes a first anti-reflective structure 20 disposed on one side 10A of the transparent substrate 10. For example, the first anti-reflective structure 20 may include be inorganic or organic material. Moreover, the first anti-reflective structure 20 may include the same or similar material to the transparent substrate 10, but the present disclosure is not limited thereto.

FIG. 1B is a partial top view illustrating the first anti-reflective structure 20 according to some embodiments of the present disclosure. It should be noted that FIG. 1B merely shows the relative relationship between the first light-path region 20L, the first raised region 20R, and the first step region 20S, but it does not show the detailed structure or the real size. As shown in FIG. 1A and FIG. 1B, in some embodiment, the first anti-reflective structure 20 has a first light-path region 20L, a first raised region 20R surrounding the first light-path region 20L, and a first step region 20S between the first light-path region 20L and the first raised region 20R.

As shown in FIG. 1A, in some embodiments, the first anti-reflective structure 20 includes first nano-structures 20N in the first light-path region 20L, and a first contact surface 10AS is defined between the first nano-structures 20N and the transparent substrate 10. In some embodiments, the first nano-structures 20N are formed as pillars, cones, prisms, or pyramids, but the present disclosure is not limited thereto. As shown in FIG. 1A, in some embodiments, the first nano-structures 20N are formed into multiple protruding structures that define multiple holes 20NH. In other words, the first nano-structures 20N may be sidewalls of the holes 20NH. The shape of the first nano-structures 20N may be adjusted according to actual needs. Moreover, the arrangement of the first nano-structures 20N may be regular (e.g., periodic arrangement) or irregular (e.g., random arrangement).

As shown in FIG. 1A, in some embodiments, the thickness T1 of the first anti-reflective structure 20 in the first raised region 20R from the first contact surface 10AS is greater than the thickness T2 of the first anti-reflective structure 20 in the first light-path region 20L from the first contact surface 10AS. In some embodiments, the thickness T1 of the first anti-reflective structure 20 in the first raised region 20R from the first contact surface 10AS is at least twice the thickness T2 of the first anti-reflective structure 20 in the first light-path region 20L from the first contact surface 10AS. The first raised region 20R may provide a transfer surface for following process (e.g., process for forming the second anti-reflective structure 30 or a bonding process).

In some embodiments, from a cross-sectional view (e.g., the cross-sectional view shown in FIG. 1A), the width W20R of the first raised region 20R is at least ten times the width W20N of each first nano-structure 20N. Moreover, in some embodiments, the ratio of the distance P20N between two adjacent first nano-structures 20N to the thickness T2 of the first anti-reflective structure 20 in the first light-path region 20L from the first contact surface 10AS is smaller than 2 (i.e., P20N/T2<2).

In some embodiments, from a cross-sectional view (e.g., the cross-sectional view shown in FIG. 1A), the width W20S of the first step region 20S is greater than about 5 nm. In other words, a step that is long enough (i.e., the first step region 20S) is around the first nano-structures 20N, which is helpful for a stable lithography process during the method for manufacturing a solid-state image sensor.

Moreover, as the cross-sectional view shown in FIG. 1A, in some embodiments, a rounded corner θ1 is formed between the first raised region 20R and the first step region 20S, but the present disclosure is not limited thereto. In some other embodiments, an included angle between the first raised region 20R and the first step region 20S in a cross-sectional view is a sharp corner.

As shown in FIG. 1A, in some embodiments, the transparent substrate 10 has recessed portions 10H that correspond to the first light-path region 20L and the first step region 20S of the first anti-reflective structure. That is, in this embodiment, the first nano-structures 20N are disposed in the recessed portions 10H.

As shown in FIG. 1A, in some embodiments, the optical protection structure 101 further includes a second anti-reflective structure 30 disposed on another side 10B of the transparent substrate 10. Similarly, the second anti-reflective structure 30 may include be inorganic or organic material. Moreover, the second anti-reflective structure 30 may include the same or similar material to the first anti-reflective structure 20, but the present disclosure is not limited thereto.

The partial top view of the second anti-reflective structure 30 may be similar to the partial top view of the first anti-reflective structure 20 as shown in FIG. 1B, but the present disclosure is not limited thereto. As shown in FIG. 1A, in some embodiment, the second anti-reflective structure 30 has a second light-path region 30L, a second raised region 30R surrounding the second light-path region 30L, and a second step region 30S between the second light-path region 30L and the second raised region 30R. FIG. 1B is a partial top view illustrating the second anti-reflective structure 30 according to some embodiments of the present disclosure.

As shown in FIG. 1A, in some embodiments, the second anti-reflective structure 30 includes second nano-structures 30N in the second light-path region 30L, and a second contact surface 10BS is defined between the second nano-structures 30N and the transparent substrate 10. In some embodiments, the second nano-structures 30N are formed as pillars, cones, prisms, or pyramids, but the present disclosure is not limited thereto. As shown in FIG. 1A, in some embodiments, the second nano-structures 30N are formed into multiple protruding structures that define multiple holes 30NH. In other words, the second nano-structures 30N may be sidewalls of the holes 20NH. The shape of the second nano-structures 30N may be adjusted according to actual needs. Moreover, the arrangement of the second nano-structures 30N may be regular (e.g., periodic arrangement) or irregular (e.g., random arrangement).

As shown in FIG. 1A, in some embodiments, the thickness T3 of the second anti-reflective structure 30 in the second raised region 30R from the second contact surface 10BS is greater than the thickness T4 of the second anti-reflective structure 30 in the second light-path region 30L from the second contact surface 10BS. In some embodiments, the thickness T3 of the second anti-reflective structure 30 in the second raised region 30R from the second contact surface 10BS is at least twice the thickness T4 of the second anti-reflective structure 30 in the second light-path region 30L from the second contact surface 10BS. The second raised region 30R may provide a transfer surface for following process (e.g., a bonding process).

In some embodiments, from a cross-sectional view (e.g., the cross-sectional view shown in FIG. 1A), the width W30R of the second raised region 30R is at least ten times the width W30N of each second nano-structure 30N. Moreover, in some embodiments, the ratio of the distance P30N between two adjacent second nano-structures 30N to the thickness T4 of the second anti-reflective structure 30 in the second light-path region 30L from the second contact surface 10BS is smaller than 2 (i.e., P30N/T4<2).

In some embodiments, from a cross-sectional view (e.g., the cross-sectional view shown in FIG. 1A), the width W30S of the second step region 30S is greater than about 5 nm. In other words, a step that is long enough (i.e., the second step region 30S) is around the second nano-structures 30N, which is helpful for a stable lithography process during the method for manufacturing a solid-state image sensor.

Moreover, as the cross-sectional view shown in FIG. 1A, in some embodiments, a sharp corner θ2 is formed between the second raised region 30R and the second step region 30S, but the present disclosure is not limited thereto. In some other embodiments, an included angle between the second raised region 30R and the second step region 30S in a cross-sectional view is a rounded corner (similar to θ2).

As shown in FIG. 1A, in some embodiments, the transparent substrate 10 has recessed portions 10H that correspond to the second light-path region 30L and the second step region 30S of the second anti-reflective structure. That is, in this embodiment, the second nano-structures 30N are disposed in the recessed portions 10H.

In some embodiment, a method for forming the optical protection structure 101 includes the following steps. A first anti-reflective film (20M) is formed on one side 10A of a transparent substrate 10. The first anti-reflective film (20M) is patterned to form a first anti-reflective structure 20. The first anti-reflective structure 20 has a first light-path region 20L, a first raised region 20R surrounding the first light-path region 20L, and a first step region 20S between the first light-path region 20L and the first raised region 20R. The first anti-reflective structure 20 includes first nano-structures 20N in the first light-path region 20L, and a first contact surface 10AS is defined between the first nano-structures 20N and the transparent substrate 10. The thickness T1 of the first anti-reflective structure 20 in the first raised region 20R from the first contact surface 10AS is greater than the thickness T2 of the first anti-reflective structure 20 in the first light-path region 20L from the first contact surface 10AS.

In some embodiments, the method for forming the optical protection structure 101 further includes the following steps. A second anti-reflective film (30M) is formed on another side 10B of the transparent substrate 10. The second anti-reflective film (30M) is patterned to form a second anti-reflective structure 30. The second anti-reflective structure 30 has a second light-path region 30L, a second raised region 30R surrounding the second light-path region 30L, and a second step region 30S between the second light-path region 30L and the second raised region 30S. The second anti-reflective structure 30 includes second nano-structures 30N in the second light-path region 30L, and a second contact surface 10BS is defined between the second nano-structures 30N and the transparent substrate 10. The thickness T3 of the second anti-reflective structure 30 in the second raised region 30R from the second contact surface 10BS is greater than the thickness T4 of the second anti-reflective structure 30 in the second light-path region 30L from the second contact surface 10BS.

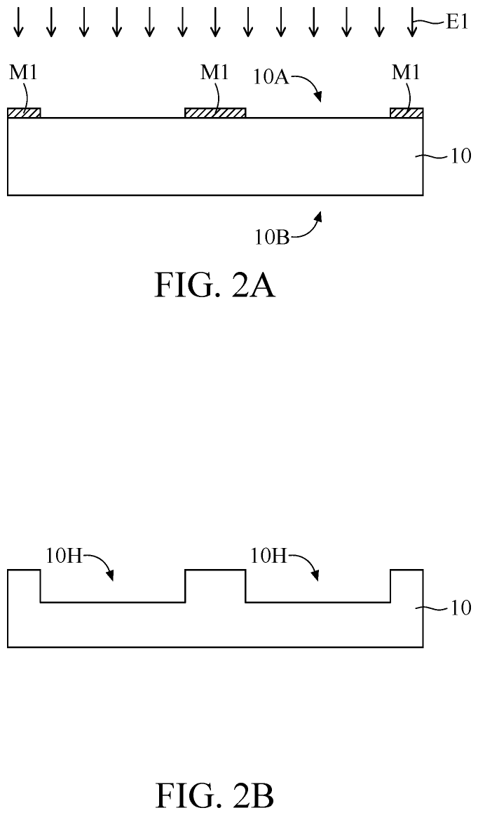

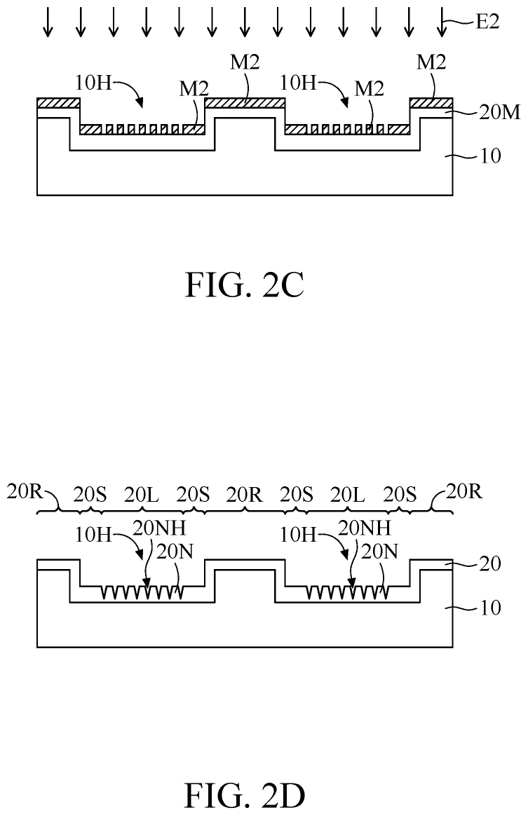

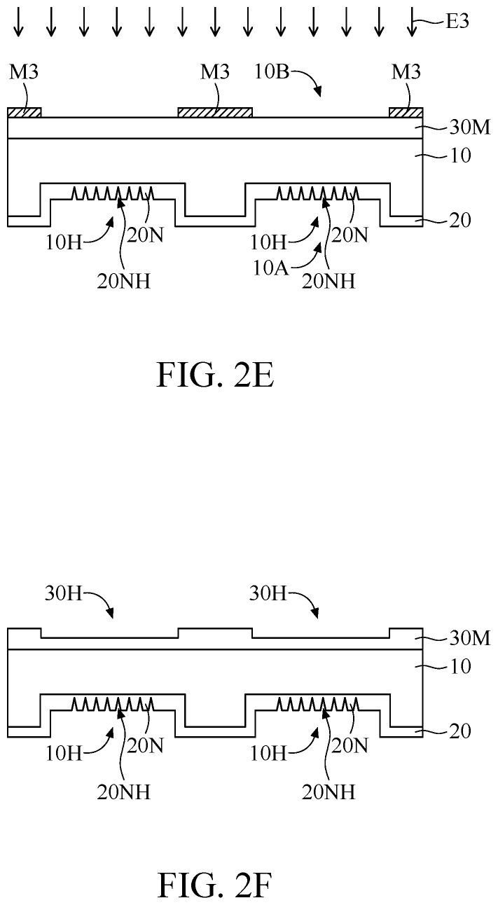

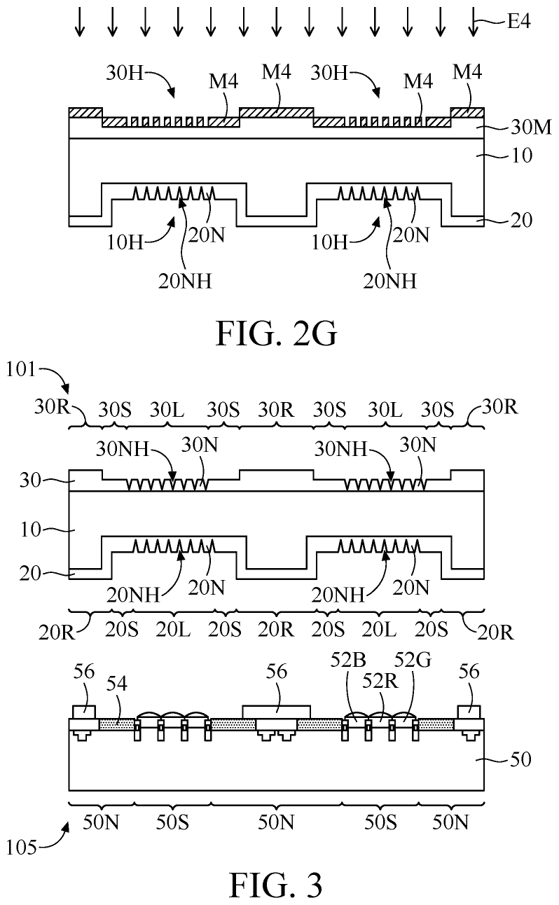

FIG. 2A to FIG. 2G are partial cross-sectional views illustrating a method for forming the optical protection structure 101 at various stages according to some embodiments of the present disclosure. Similarly, some components of the optical protection structure 101 have been omitted in FIG. 2A to FIG. 2G for the sake of brevity.

As shown in FIG. 2A and FIG. 2B, a transparent substrate 10 is patterned to form recessed portions 10H by a wet etching process E1. For example, the wet etching process E1 may use, for example, hydrofluoric acid (HF), ammonium hydroxide (NH₄OH), or any suitable etchant, but the present disclosure is not limited thereto.

In more detail, as shown in FIG. 2A, a mask layer M1 may be formed on the one side 10A of the transparent substrate 10, and then the wet etching process E1 may be performed to etch the transparent substrate 10 using the mask layer M1 as an etch mask. For example, the mask layer M1 may include silicon oxide (SiO₂), silicon nitride (SiN), silicon oxynitride (SiON), silicon carbide (SiC), silicon carbonitride (SiCN), the like, or a combination thereof, but the present disclosure is not limited thereto. Alternately, the mask layer M1 may include a photoresist, such as a positive photoresist or a negative photoresist. For example, the mask layer M1 may include photoresist, ink, molding compound, solder mask, epoxy polymer, any other applicable material, or a combination thereof. The mask layer may be a single-layer structure or a multi-layer structure.

The mask layer M1 may be formed by a deposition process, a photolithography process, any other suitable process, or a combination thereof, but the present disclosure is not limited thereto. For example, the deposition process may include spin-on coating, chemical vapor deposition (CVD), atomic layer deposition (ALD), the like, or a combination thereof. For example, the photolithography process may include photoresist coating (e.g., spin coating), soft baking, mask aligning, exposure, post-exposure baking (PEB), developing, rinsing, drying (e.g., hard baking), other suitable processes, or a combination thereof, but the present disclosure is not limited thereto. Then, as shown in FIG. 2B, after the wet etching process E1, the mask layer M1 is removed and recessed portions 10H are formed.

As shown in FIG. 2C, a first anti-reflective film 20M is formed on the patterned transparent substrate 10, and a portion of the first anti-reflective film 20M is formed in the recessed portions 10H. For example, the first anti-reflective film 20M may include an oxide and be formed by a deposition process, but the present disclosure is not limited thereto. Then, a mask layer M2 may be formed on the first anti-reflective film 20M, and a dry etching process E2 may be performed to etch the first anti-reflective film 20M using the mask layer M2 as an etch mask.

The mask layer M2 may include a similar material to the mask layer M1, but the present disclosure is not limited thereto. The dry etching process may include reactive ion etch (RIE), inductively-coupled plasma (ICP) etching, neutral beam etching (NBE), electron cyclotron resonance (ERC) etching, the like, or a combination thereof, but the present disclosure is not limited thereto.

Then, as shown in FIG. 2D, after the dry etching process E2, the mask layer M2 is removed and the first anti-reflective structure 20 (that includes first nano-structures 20N and holes 20NH) is formed. In this stage, the first anti-reflective structure 20 is divided into a first light-path region 20L, a first raised region 20R surrounding the first light-path region 20L, and a first step region 20S between the first light-path region 20L and the first raised region 20R.

As shown in FIG. 2D, the first light-path region 20L and the first step region 20S of the first anti-reflective structure 20 correspond to the recessed portions 10H of the (patterned) transparent substrate 10, and the first nano-structures 20N (and the holes 20NH) are disposed in the recessed portions 10H of the (patterned) transparent substrate 10.

As shown in FIG. 2E, the structure shown in FIG. 2D is turned upside down, and a second anti-reflective film 30M is formed on another side 10B of the transparent substrate 10. Then, a mask layer M3 may be formed on the second anti-reflective film 30M, and a dry etching process E3 may be performed to etch second anti-reflective film 30M using the mask layer M3 as an etch mask. The mask layer M3 may include a similar material to the mask layer M1 or M2, but the present disclosure is not limited thereto.

Then, as shown in FIG. 2F, after the dry etching process E3, the mask layer M3 is removed and the second anti-reflective film 30M is patterned to form recessed portions 30H. As shown in FIG. 2G, a mask layer M4 may be formed on the (patterned) second anti-reflective film 30M. Then, a dry etching process E4 may be performed to etch the (patterned) second anti-reflective film 30M (i.e., the recessed portions 30H) using the mask layer M4 as an etch mask to form a second light-path region 30L and a second step region 30S. The mask layer M4 may include a similar material to the mask layer M1, M2, or M3, but the present disclosure is not limited thereto.

Then, as shown in FIG. 1A, after the dry etching process E4, the mask layer M4 is removed and the second anti-reflective structure 30 (that includes second nano-structures 30N and holes 30NH) is formed. In this stage, the second anti-reflective structure 30 is divided into a second light-path region 30L, a second raised region 30R surrounding the second light-path region 30L, and a second step region 30S between the second light-path region 30L and the second raised region 30R.

FIG. 3 is a partial cross-sectional view illustrating a stage for bonding the optical protection structure 101 to a solid-state image sensor 105. As shown in FIG. 3, in some embodiments, the solid-state image sensor 105 includes an operating substrate 50 that has a sensing area 50S and a non-sensing area 50N surrounding the sensing area 50S. The solid-state image sensor 105 also includes light-emitting structures 52B, 52R, and 52G disposed on the operating substrate 50 and corresponding to the sensing area 50S. The solid-state image sensor 105 further includes light-shielding structures 54 surrounding the light-emitting structures 52B, 52R, and 52G and corresponding to the non-sensing area 50N.

As shown in FIG. 3, in some embodiments, the first raised region 20R of the first anti-reflective structure 20 may be aligned with the non-sensing area 50N of the operating substrate 50. Moreover, the first light-path region 20L and the first step region 20S of the first anti-reflective structure 20 may be aligned with the sensing area 50N of the operating substrate 50. In this example, the optical protection structure 101 may be bonded to the solid-state image sensor 105 by the glue 56 on the sensing area 50N of the operating substrate 50 to protect the light-emitting structures 52B, 52R, and 52G and possess anti-reflective properties.

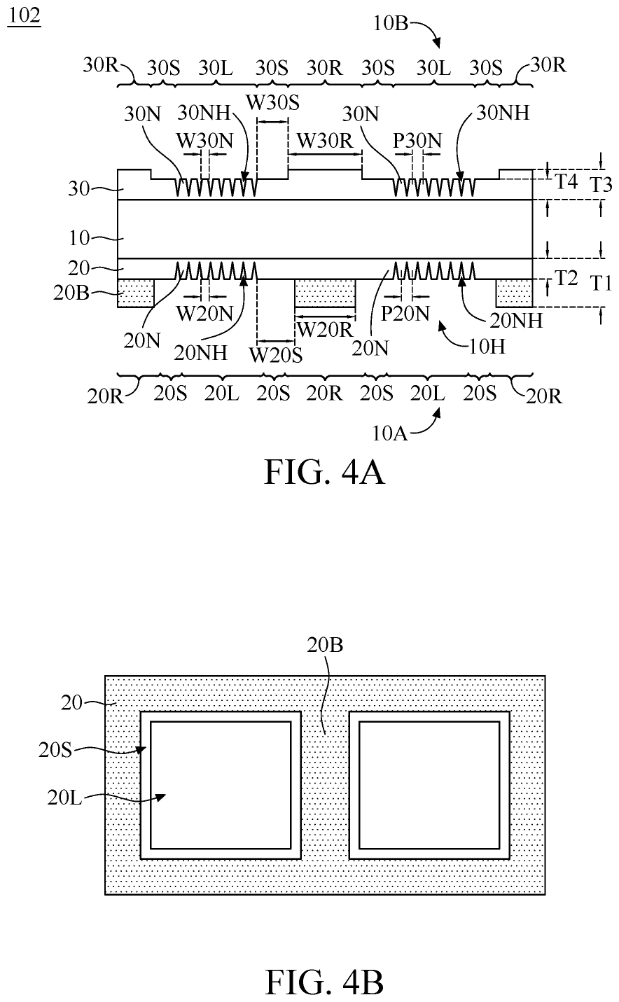

FIG. 4A is a partial cross-sectional view illustrating an optical protection structure 102 according to some other embodiments of the present disclosure. FIG. 4B is a partial top view illustrating the first anti-reflective structure 20 according to some embodiments of the present disclosure. Similarly, FIG. 4B merely shows the relative relationship between the first light-path region 20L, the first raised region 20R, and the first step region 20S, but it does not show the detailed structure or the real size. Moreover, some components of the optical protection structure 102 have been omitted in FIG. 4A and FIG. 4B for the sake of brevity.

The optical protection structure 102 shown in FIG. 4A may have a similar structure to the optical protection structure 101 shown in FIG. 1A. The main difference from the optical protection structure 101 is that the first anti-reflective structure 20 of the optical protection structure 102 further includes light-shielding structures 20B in the first raised region 20R as shown in FIG. 4A and FIG. 4B.

For example, the light-shielding structures 20B may include photoresist (e.g., black photoresist, or other applicable photoresist which is not transparent), ink (e.g., black ink, or other applicable ink which is not transparent), molding compound (e.g., black molding compound, or other applicable molding compound which is not transparent), solder mask (e.g., black solder mask, or other applicable solder mask which is not transparent), (black) epoxy polymer, any other applicable material, or a combination thereof. Moreover, the light-shielding structures 20B includes a light curing material, a thermal curing material, or a combination thereof.

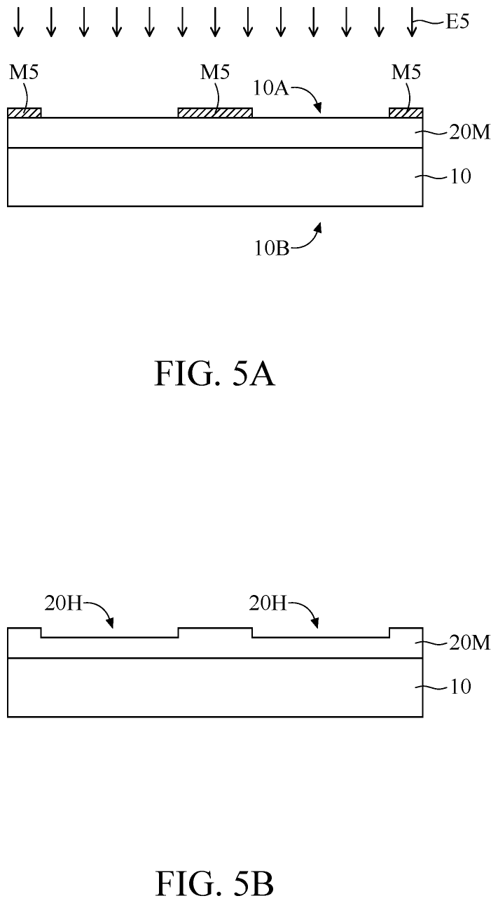

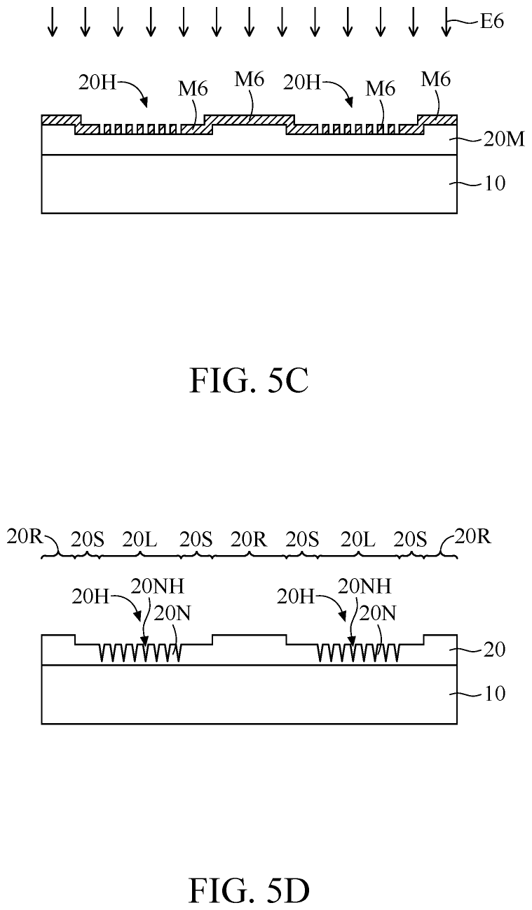

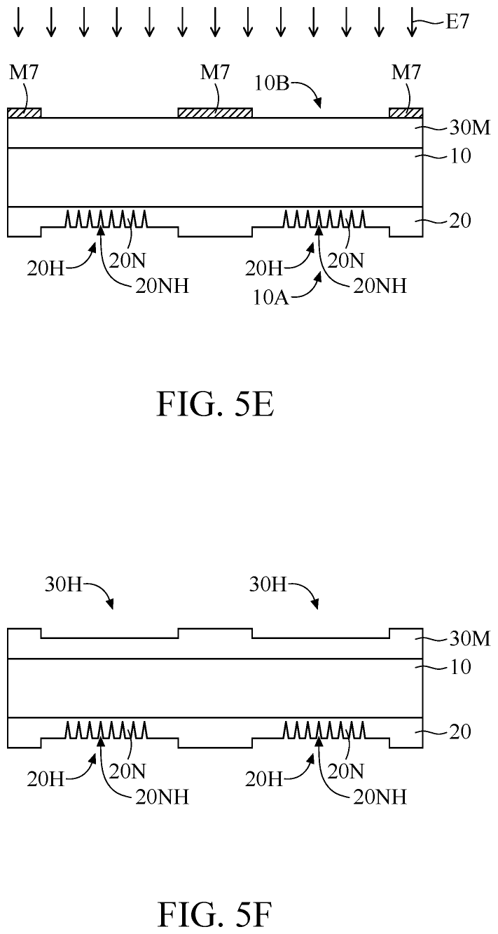

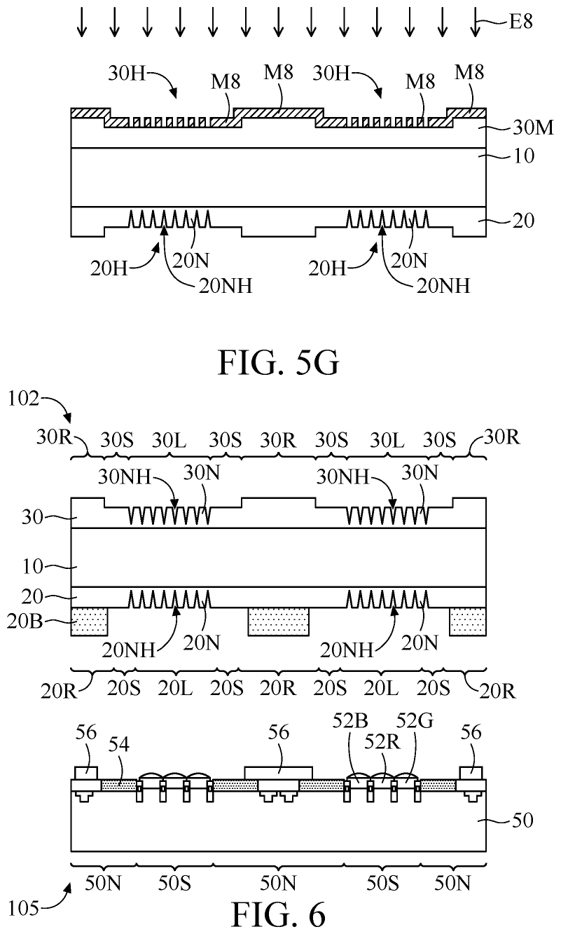

FIG. 5A to FIG. 5G are partial cross-sectional views illustrating a method for forming the optical protection structure 102 at various stages according to some other embodiments of the present disclosure. Similarly, some components of the optical protection structure 102 have been omitted in FIG. 5A to FIG. 5G for the sake of brevity.

As shown in FIG. 5A, a first anti-reflective film 20M is formed on one side 10A of the transparent substrate 10. Then, a mask layer M5 may be formed on the first anti-reflective film 20M, and a dry etching process E5 may be performed to etch first anti-reflective film 20M using the mask layer M5 as an etch mask. The mask layer M5 may include a similar material to the mask layer M1 to M4, but the present disclosure is not limited thereto.

Then, as shown in FIG. 5B, after the dry etching process E5, the mask layer M3 is removed and the first anti-reflective film 20M is patterned to form recessed portions 20H. As shown in FIG. 5C, a mask layer M6 may be formed on the (patterned) first anti-reflective film 20M. Then, a dry etching process E6 may be performed to etch the (patterned) first anti-reflective film 20M (i.e., the recessed portions 20H) using the mask layer M6 as an etch mask to form a first light-path region 20L and a first step region 20S. The mask layer M6 may include a similar material to the mask layer M1 to M5, but the present disclosure is not limited thereto.

Then, as shown in FIG. 5D, after the dry etching process E6, the mask layer M6 is removed and the first anti-reflective structure 20 (that includes first nano-structures 20N and holes 20NH) is formed. In this stage, the first anti-reflective structure 20 is divided into a first light-path region 20L, a first raised region 20R surrounding the first light-path region 20L, and a first step region 20S between the first light-path region 20L and the first raised region 20R.

As shown in FIG. 5E, the structure shown in FIG. 5D is turned upside down, and a second anti-reflective film 30M is formed on another side 10B of the transparent substrate 10. Then, a mask layer M7 may be formed on the second anti-reflective film 30M, and a dry etching process E7 may be performed to etch second anti-reflective film 30M using the mask layer M7 as an etch mask. The mask layer M7 may include a similar material to the mask layer M1 to M6, but the present disclosure is not limited thereto.

Then, as shown in FIG. 5F, after the dry etching process E7, the mask layer M7 is removed and the second anti-reflective film 30M is patterned to form recessed portions 30H. As shown in FIG. 5G, a mask layer M8 may be formed on the (patterned) second anti-reflective film 30M. Then, a dry etching process E8 may be performed to etch the (patterned) second anti-reflective film 30M (i.e., the recessed portions 30H) using the mask layer M8 as an etch mask to form a second light-path region 30L and a second step region 30S. The mask layer M8 may include a similar material to the mask layer M1 to M7, but the present disclosure is not limited thereto.

Then, as shown in FIG. 4A, after the dry etching process E8, the mask layer M8 is removed and the second anti-reflective structure 30 (that includes second nano-structures 30N and holes 30NH) is formed. In this stage, the second anti-reflective structure 30 is divided into a second light-path region 30L, a second raised region 30R surrounding the second light-path region 30L, and a second step region 30S between the second light-path region 30L and the second raised region 30R.

FIG. 6 is a partial cross-sectional view illustrating a stage for bonding the optical protection structure 102 to a solid-state image sensor 105. As shown in FIG. 6, in some embodiments, the light-shielding structures 20B in the first raised region 20R may be aligned with the non-sensing area 50N of the operating substrate 50. Moreover, the first light-path region 20L and the first step region 20S of the first anti-reflective structure 20 may be aligned with the sensing area 50N of the operating substrate 50. In this example, the optical protection structure 102 may be bonded to the solid-state image sensor 105 by the glue 56 on the sensing area 50N of the operating substrate 50 to protect the light-emitting structures 52B, 52R, and 52G and possess anti-reflective properties.

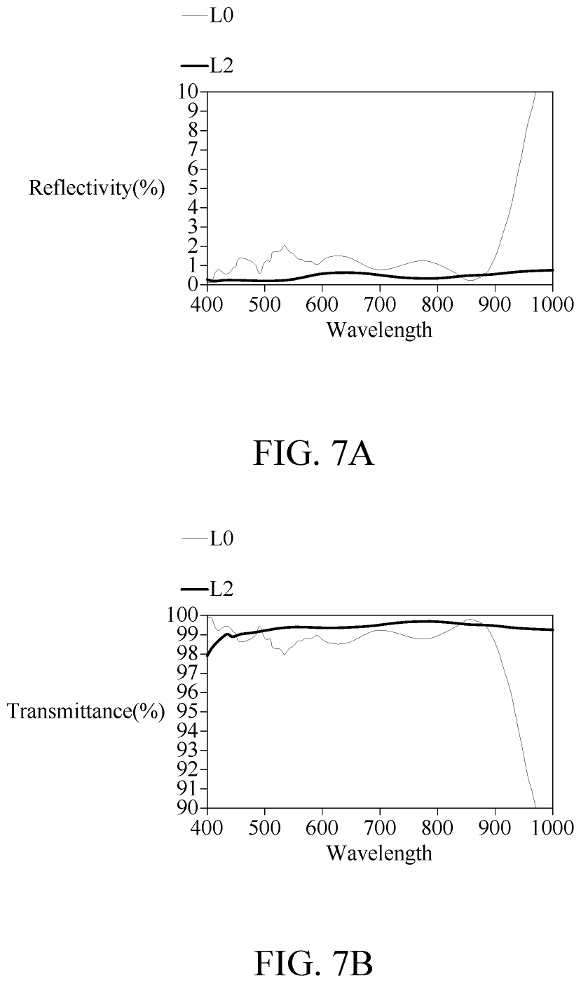

FIG. 7A illustrates the reflectivity of the traditional optical protection structure (line L0, which includes flat glass with multi-film layers) and the reflectivity of the optical protection structure (e.g., optical protection structure 101) according to the embodiment of the present disclosure (line L2, which includes two anti-reflective structure) at various wavelengths. FIG. 7B illustrates the transmittance of the traditional optical protection structure (line L0) and the reflectivity of the optical protection structure (e.g., optical protection structure 101) according to the embodiment of the present disclosure (line L2) at various wavelengths.

As shown in FIG. 7A, compared to the traditional optical protection structure, the optical protection structure according to the embodiment of the present disclosure keeps low reflectivity even at long wavelength. That is, the optical protection structure according to the embodiment of the present disclosure has better anti-reflection compared to the traditional optical protection structure.

As shown in FIG. 7B, compared to the traditional optical protection structure, the optical protection structure according to the embodiment of the present disclosure keeps high reflectivity even at long wavelength. That is, the optical protection structure according to the embodiment of the present disclosure has better transmittance compared to the traditional optical protection structure.

In summary, the optical protection structure according to the embodiment of the present disclosure includes at least one anti-reflective structure. The anti-reflective structure has a light-path region, a raised region surrounding the light-path region, and a step region between the first light-path region and the first raised region. The raised region and the step region may effectively prevent the anti-reflective structure from being damaged during the forming process and provide better anti-reflection and transmittance at long-wavelength and large incident angle.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure. Therefore, the scope of protection should be determined through the claims. In addition, although some embodiments of the present disclosure are disclosed above, they are not intended to limit the scope of the present disclosure.

Reference throughout this specification to features, advantages, or similar language does not imply that all of the features and advantages that may be realized with the present disclosure should be or are in any single embodiment of the disclosure. Rather, language referring to the features and advantages is understood to mean that a specific feature, advantage, or characteristic described in connection with an embodiment is included in at least one embodiment of the present disclosure. Thus, discussions of the features and advantages, and similar language, throughout this specification may, but do not necessarily, refer to the same embodiment.

Furthermore, the described features, advantages, and characteristics of the disclosure may be combined in any suitable manner in one or more embodiments. One skilled in the relevant art will recognize, in light of the description herein, that the disclosure can be practiced without one or more of the specific features or advantages of a particular embodiment. In other instances, additional features and advantages may be recognized in certain embodiments that may not be present in all embodiments of the disclosure.

What is claimed is:

1. An optical protection structure, comprising:
a transparent substrate; and
a first anti-reflective structure disposed on one side of the transparent substrate, wherein the first anti-reflective structure has a first light-path region, a first raised region surrounding the first light-path region, and a first step region between the first light-path region and the first raised region,
wherein the first anti-reflective structure comprises first nano-structures in the first light-path region, and a first contact surface is defined between the first nano-structures and the transparent substrate, and
wherein a thickness of the first anti-reflective structure in the first raised region from the first contact surface is greater than a thickness of the first anti-reflective structure in the first light-path region from the first contact surface.

2. The optical protection structure as claimed in claim 1, wherein the thickness of the first anti-reflective structure in the first raised region from the first contact surface is at least twice the thickness of the first anti-reflective structure in the first light-path region from the first contact surface.

3. The optical protection structure as claimed in claim 1, wherein from a cross-sectional view, a width of the first raised region is at least ten times a width of each of the first nano-structures.

4. The optical protection structure as claimed in claim 1, wherein the ratio of a distance between adjacent two of the first nano-structures to the thickness of the first anti-reflective structure in the first light-path region from the first contact surface is smaller than 2.

5. The optical protection structure as claimed in claim 1, wherein from a cross-sectional view, a width of the first step region is greater than 5 nm, and a sharp corner or a rounded corner is formed between the first raised region and the first step region.

6. The optical protection structure as claimed in claim 1, wherein the first nano-structures are formed as pillars, cones, prisms, or pyramids.

7. The optical protection structure as claimed in claim 1, wherein the first nano-structures are formed into multiple protruding structures that define multiple holes.

8. The optical protection structure as claimed in claim 1, wherein the transparent substrate has recessed portions that correspond to the first light-path region and the first step region, and the first nano-structures are disposed in the recessed portions.

9. The optical protection structure as claimed in claim 1, wherein the first anti-reflective structure further comprises light-shielding structures in the first raised region.

10. The optical protection structure as claimed in claim 1, further comprising:
a second anti-reflective structure disposed on another side of the transparent substrate, wherein the second anti-reflective structure has a second light-path region, a second raised region surrounding the second light-path region, and a second step region between the second light-path region and the second raised region,
wherein the second light-path region corresponds to the first light-path region, and the second raised region corresponds to the first raised region,
wherein the second anti-reflective structure comprises second nano-structures in the second light-path region, and a second contact surface is defined between the second nano-structures and the transparent substrate, and
wherein a thickness of the second anti-reflective structure in the second raised region from the second contact surface is greater than a thickness of the second anti-reflective structure in the second light-path region from the second contact surface.

11. The optical protection structure as claimed in claim 10, wherein the thickness of the second anti-reflective structure in the second raised region from the second contact surface is at least twice the thickness of the second anti-reflective structure in the second light-path region from the second contact surface.

12. The optical protection structure as claimed in claim 10, wherein from a cross-sectional view, a width of the second raised region is at least ten times a width of each of the second nano-structures.

13. The optical protection structure as claimed in claim 10, wherein the ratio of a distance between adjacent two of the second nano-structures to the thickness of the second anti-reflective structure in the second light-path region from the second contact surface is smaller than 2.

14. The optical protection structure as claimed in claim 10, wherein from a cross-sectional view, a width of the second step region is greater than 5 nm, and a sharp corner or a rounded corner is formed between the second raised region and the second step region.

15. The optical protection structure as claimed in claim 10, wherein the second nano-structures are formed as pillars, cones, prisms, or pyramids.

16. The optical protection structure as claimed in claim 10, wherein the second nano-structures are formed into multiple protruding structures that define multiple holes.

17. A method for forming an optical protection structure, comprising:
forming a first anti-reflective film on one side of a transparent substrate;
patterning the first anti-reflective film to form a first anti-reflective structure, wherein the first anti-reflective structure has a first light-path region, a first raised region surrounding the first light-path region, and a first step region between the first light-path region and the first raised region,
wherein the first anti-reflective structure comprises first nano-structures in the first light-path region, and a first contact surface is defined between the first nano-structures and the transparent substrate, and
wherein a thickness of the first anti-reflective structure in the first raised region from the first contact surface is greater than a thickness of the first anti-reflective structure in the first light-path region from the first contact surface.

18. The method for forming the optical protection structure as claimed in claim 17, further comprising:
patterning the transparent substrate to form recessed portions by a wet etching process, so that a portion of the first anti-reflective film is formed in the recessed portions,
wherein the first light-path region and the first step region correspond to the recessed portions, and the first nano-structures are disposed in the recessed portions.

19. The method for forming the optical protection structure as claimed in claim 17, wherein the steps of patterning the first anti-reflective film comprises:
performing a first dry etching process on the first anti-reflective film to form the first raised region and a recess portion; and
performing a second dry etching process on the recess portion to form the first light-path region and the first step region.

20. The method for forming the optical protection structure as claimed in claim 17, further comprising:
forming a second anti-reflective film on another side of the transparent substrate;
patterning the second anti-reflective film to form a second anti-reflective structure, wherein the second anti-reflective structure has a second light-path region, a second raised region surrounding the second light-path region, and a second step region between the second light-path region and the second raised region,
wherein the second anti-reflective structure comprises second nano-structures in the second light-path region, and a second contact surface is defined between the second nano-structures and the transparent substrate, and
wherein a thickness of the second raised region from the second contact surface is greater than a thickness of the second light-path region from the second contact surface.
